(19) United States
(12) Patent Application Publication
(10) Pub. No.: US 2025/0206601 A1
(43) Pub. Date: Jun. 26, 2025

(54) DIFFERENTIAL MICROPHONE ASSEMBLY

(71) Applicant: Soundskrit Inc., Montreal (CA)

(72) Inventors: Carly Stalder, Montreal (CA); Stephane Leahy, Montreal (CA); Sahil Gupta, Montreal (CA)

(21) Appl. No.: 18/990,978

(22) Filed: Dec. 20, 2024

Related U.S. Application Data
(60) Provisional application No. 63/613,216, filed on Dec. 21, 2023.

(51) Int. Cl. B81B 7/04; H04R 1/40

(52) U.S. Cl. CPC B81B 7/04; H04R 1/406; B81B 2201/0257; B81B 2203/0118; B81B 2203/04; H04R 2201/003

(57) ABSTRACT

A microphone module includes a first microelectromechanical system (MEMS) transducer comprising a first cantilever and a first fixed electrode and a second MEMS transducer comprising a second cantilever and a second fixed electrode. The first MEMS transducer and the second MEMS transducer are arranged in the microphone module such that when a sound wave traverses the microphone module the sound wave causes the first MEMS transducer and the second MEMS transducer to move in different directions with respect to each other.

### CROSS-REFERENCES TO RELATED APPLICATIONS

This application claims the benefit of U.S. provisional application entitled “Differential Microphone Assembly,” filed Dec. 21, 2023, and assigned Ser. No. 63/613,216, the entire disclosure of which is hereby expressly incorporated by reference.

### BACKGROUND OF THE DISCLOSURE

### Field of the Disclosure

The disclosure relates generally to acoustic sensor devices such as microelectromechanical system (MEMS) microphones.

### Brief Description of Related Technology

In some traditional omnidirectional microphones using MEMS transducers, a dual-backplate structure is used. A membrane is constructed that is free to vibrate between two fixed backplates. The membrane typically holds a bias voltage and induces a voltage or charge on the two black plates with an opposite polarity. This creates a differential signal between the two backplates that can be amplified by an application-specific integrated circuit (ASIC) or other circuitry. When subtracting the two signals on the backplates, the signal is doubled due to the opposite polarity of the two signals. However, any common mode signals between the backplates effectively cancel out. For example, the differential configuration can be used to reduce distortion and non-linearities seen in the MEMS transducer, thus increasing the acoustic overload point of the microphone.

Some MEMS directional microphones employ a cantilever-based design using a moving cantilever with interdigitated fingers rather than fixed backplates as used in omnidirectional microphones. A traditional dual-backplate sensing architecture cannot be used to generate a differential signal.

### SUMMARY OF THE DISCLOSURE

In accordance with one aspect of the disclosure, a microphone module incudes a first microelectromechanical system (MEMS) transducer comprising a first cantilever and a first fixed electrode and a second MEMS transducer comprising a second cantilever and a second fixed electrode. The first MEMS transducer and the second MEMS transducer are arranged in the microphone module such that when a sound wave traverses the microphone module the sound wave causes the first MEMS transducer and the second MEMS transducer to move in different directions with respect to each other.

In accordance with another aspect of the disclosure, a microphone module includes a first microelectromechanical system (MEMS) transducer comprising a first cantilever and a first fixed electrode and a second MEMS transducer comprising a second cantilever and a second fixed electrode. The first MEMS transducer and the second MEMS transducer are arranged in the microphone module such that, when a sound wave traverses the microphone module, the sound wave causes the first MEMS transducer and the second MEMS transducer to generate respective output signals that are opposite in phase with respect to each other.

In accordance with yet another aspect of the disclosure, a microphone module includes a first microelectromechanical system (MEMS) transducer comprising a first cantilever and a first fixed electrode and a second MEMS transducer comprising a second cantilever and a second fixed electrode. The microphone module also includes a common substrate that supports the first MEMS transducer and the second MEMS transducer. The first MEMS transducer and the second MEMS transducer are positioned on opposing sides of the common substrate such that, when a sound wave traverses the microphone module, the sound wave causes the first MEMS transducer and the second MEMS transducer to generate respective output signals that are opposite in phase with respect to each other.

In connection with any one of the aforementioned aspects, the devices and/or methods described herein may alternatively or additionally include or involve any combination of one or more of the following aspects or features. The first MEMS transducer and the second MEMS transducer are arranged in the microphone module such that when a sound wave traverses the microphone module the sound wave causes the first MEMS transducer and the second MEMS transducer to move in different directions that are opposite of each other. The microphone module further comprises a first sound port and a second sound port. The first MEMS transducer is positioned in the microphone module over the first sound port and the second MEMS transducer is positioned in the microphone module over the second sound port. The first sound port is offset from the second sound port. The first sound port and the second sound port are aligned with each other. The first MEMS transducer and the second MEMS transducer are fabricated to be identical to each other. The first MEMS transducer and the second MEMS transducer are arranged such that, as the sound wave traverses the microphone module, the sound wave makes the first cantilever move towards the first fixed electrode as the second cantilever is moving away from the second fixed electrode. The first cantilever has an equilibrium position such that the first cantilever is deflected in a first direction relative to the first fixed electrode. The second cantilever has an equilibrium position such that the second cantilever is deflected in the first direction relative to the second fixed electrode. The first cantilever has an equilibrium position such that the first cantilever is deflected downwards relative to the first fixed electrode. The second cantilever has an equilibrium position such that the second cantilever is deflected downwards relative to the second fixed electrode. The microphone module further comprises a first substrate that supports the first MEMS transducer and a second substrate that supports the second MEMS transducer. The microphone module further comprises a common substrate, wherein the first substrate that supports the first MEMS transducer and the second substrate that supports the second MEMS transducer are positioned on opposing sides of the common substrate. The common substrate comprises a printed circuit board (PCB). The microphone module further comprises a first lid positioned over the first substrate and enclosing the first MEMS transducer and a second lid positioned over the second substrate and enclosing the second MEMS transducer. The first MEMS transducer is configured to generate a first output signal when the sound wave traverses the microphone module. The second MEMS transducer is configured to generate a second output signal when the sound wave traverses the microphone module. The second output signal is opposite in phase relative to the first output signal. The first output signal and the second output signal are subtracted to generate a differential output of the microphone module. The microphone module further comprises one or more third MEMS transducers, each of the one or more third MEMS transducers comprising a third cantilever and a third fixed electrode and one or more fourth MEMS transducers, each of the one or more fourth MEMS transducers comprising a fourth cantilever and a fourth fixed electrode. The one or more third MEMS transducers and the one or more fourth MEMS transducers are arranged in the microphone module such that as the sound wave traverses the microphone module the sound wave causes the one or more third MEMS transducer and the one or more fourth MEMS transducer to move in different directions with respect to each other. The first MEMS transducer and the one or more third MEMS transducers are arranged such that, as the sound wave traverses the microphone module, the sound wave causes the first MEMS transducer and the one or more third MEMS transducers to move in a same direction with respect to each other. The second MEMS transducer and the one or more fourth MEMS transducers are arranged such that, as the sound wave traverses the microphone module, the sound wave causes the second MEMS transducer and the one or more fourth MEMS transducers to move in a same direction with respect to each other. A first output signal generated by the first MEMS transducer and one or more third output signals generated by respective ones of the ones of more third MEMS transducers are summed to generate a first sum output signal. A second output signal generated by the second MEMS transducer and one or more fourth output signals generated by respective ones of the one or more fourth MEMS transducers are summed to generate a second sum output signal. The first sum output signal and the second sum output signal are subtracted to generate a differential output of the microphone module.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a system or device in accordance with one example in which a differential signal is created using directional microphones.

FIG. 2 depicts a system or device in accordance with another example in which a differential signal is created using at least two directional microphones with a shared PCB.

FIGS. 3A and 3B depict a system or device 300 in accordance with an example in which a differential signal is created using at least two directional microphones with misaligned sound ports.

FIGS. 4A and 4B depict a system or device 400 in accordance with an example in which more than two directional microphones are used to increase the signal-to-noise ratio (SNR) of the total system's output.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Described herein are microphone devices (or systems) configured for generation of a differential output using multiple (e.g., two) MEMS microphones. The MEMS microphones are arranged or otherwise disposed in an assembly (e.g., a packaging assembly) in a manner such that an incoming signal causes respective transducers of the MEMS microphones to move in opposite directions. In two-microphone cases, the two microphones may accordingly be considered to be oppositely phased. When the MEMS microphones have the same (or similar) configuration, such movement in opposite directions leads to the generation of equal and opposite outputs. The equal and opposite outputs are then used to generate a differential output.

Examples of the disclosed microphone devices are described herein in which the multiple MEMS microphones are packaged or positioned (e.g., mounted) in a manner such that the transducers of the MEMS microphones move in opposite directions in response to an input signal. For instance, the MEMS microphones may have opposing orientations such that the input signal drives movement in the opposite directions. In some cases, the MEMS microphones are mounted on opposite sides of a PCB board or other substrate with a shared sound path that passes through a hole in the substrate. In other cases, each MEMS microphone has a respective (non-shared) sound path through the substrate.

Each MEMS microphone may be disposed on a respective die and housed within a respective enclosure or housing. For example, two MEMS microphones may be disposed in a stacked configuration (e.g., back to back with one another). However, the packaging, positioning, orientation, and configuration of the MEMS microphones may vary. Thus, the extent to, and the manner in, which the packaging of the MEMS microphones is integrated may vary. For instance, the MEMS microphones may or may not share one or more housing structures or other packaging components.

Challenges may arise in connection with the attempt to generate equal and opposite outputs. The transducers of the MEMS microphones may have a common (e.g., cantilever-based) MEMS configuration. A common or same configuration for the MEMS transducers is useful for generation of the equal and opposite outputs. In some cases, the common configuration may include moving and fixed electrodes that include a single conductive layer (e.g., composed of, or otherwise including, polysilicon) disposed between two dielectric layers (e.g., composed of, or otherwise including, silicon nitride). Configuring the layers similarly may lead to the same amount of initial deflection for the moving electrodes, or cantilevers, of each MEMS transducer. However, differences between the MEMS transducers may arise from, e.g., manufacturing tolerance(s). Any such differences, along with the resulting deviations in respective outputs, may be addressed via calibration techniques involving, for instance, adjustments to the bias voltage and/or gain in the ASIC associated with one or both of the MEMS transducers.

Although the microphone devices are described in connection with MEMS microphones with transducers having plate-shaped moving electrodes and electrodes with interdigitated fingers, a wide variety of transducer configurations may be used. Any type of MEMS directional transducer may thus be used.

The disclosed microphone devices are not limited to examples in which the MEMS transducers are identical (or intended to be identical). Accordingly, the disclosed microphone devices may include MEMS transducers having one or more intentional differences. For instance, the MEMS transducers may be configured differently to address an issue arising from the shape, size, or other characteristic of the flow path and/or the positioning or orientation of the MEMS dies within the device enclosure.

Although generally described in connection with microphones, the disclosed devices may be acoustic sensor devices used in other applications and contexts. For instance, the disclosed devices may be useful in connection with accelerometers, gyroscopes, inertial sensors, pressure sensors, gas sensors, etc. The disclosed devices are described in the context of excitation by sound waves. However, alternative or additional stimuli may excite the devices in other contexts.

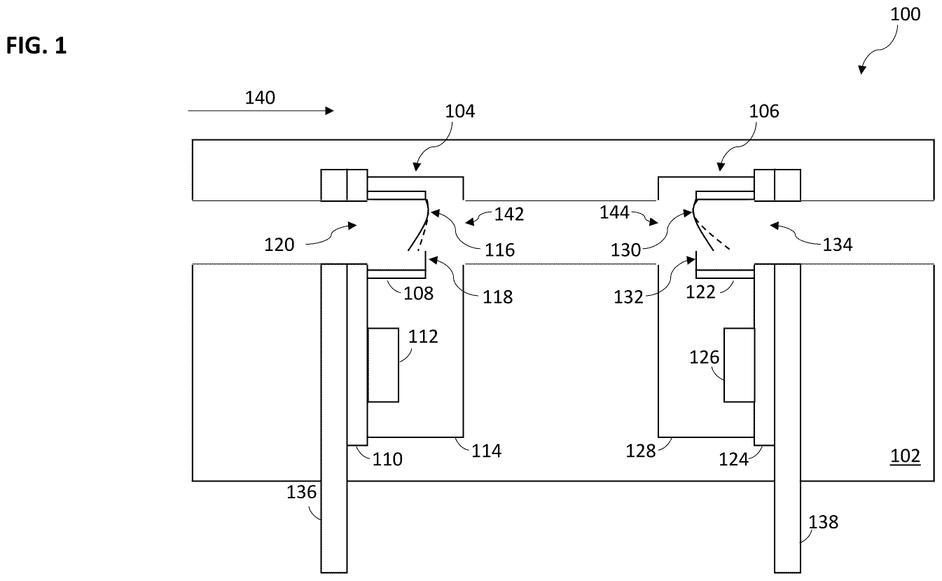

FIG. 1 depicts a system or device 100 in accordance with one example in which a differential signal is created using directional microphones. The system or device 100 is sometimes referred to herein as a “microphone module” 100. The microphone module 100 may be configured as a module to be integrated into another device or system, such as an electronic device (e.g., laptop computer). In another example, the microphone module 100 may be, or may be a part of, a part of a stand-alone microphone device. The microphone module 100 includes a gasket or enclosure 102 including at least two microphones, including at least a first microphone 104 and a second microphone 106. In an example, the first microphone 104 and the second microphone 106 are directional microphones arranged such that the microphones 104, 106 are oppositely phased with respect to each other. Accordingly, the microphone 106 is sometimes referred to herein as “an oppositely phased directional microphone 106.” As explained in more detail below, as a sound wave traverses the microphone module 100, the oppositely phased directional microphone 106 generates an output signal that is opposite in phase relative to an output signal generated by the directional microphone 104, in an example.

The directional microphone 104 is configured as, or otherwise includes, a MEMS transducer 108 supported by a substrate 110. The substrate 110 may be or include a printed circuit board (PCB) with one or multiple layers. The transducer 108 is further connected to an application-specific circuit (ASIC) 112 by wire bonds not depicted in FIG. 1. The ASIC 112 may be further protected by a globtop not depicted in FIG. 1. The transducer 108 and ASIC 112 are further encapsulated by a lid or other enclosure 114. In some examples, the lid 114 is composed of, or otherwise includes, a metal.

The transducer 108 includes a moving cantilever, or electrode, 116 and a fixed electrode 118. In some examples, the cantilever 116 may have an equilibrium (or resting) position such that it is deflected downwards (e.g., toward the substrate 110) relative to the fixed electrode 118. The transducer 108 is mounted above a left sound port 120 embedded in the PCB 110.

The oppositely phased directional microphone 106 includes a MEMS transducer 122 supported by a substrate 124. The substrate 124 may be or include a PCB with one or multiple layers. The transducer 122 is further connected to an ASIC 126 by wire bonds not depicted in FIG. 1. The ASIC 126 may be further protected by a globtop not depicted in FIG. 1. The transducer 122 and ASIC 126 are further encapsulated by a lid or other enclosure 128. In some examples, the lid 128 is composed of, or otherwise includes, a metal.

The transducer 122 includes a moving cantilever, or electrode, 130 and a fixed electrode 132. In some examples, the cantilever 130 may have an equilibrium (or resting) position such that it is deflected downwards (e.g., toward the substrate 124) relative to the fixed electrode 132. The transducer 122 is mounted above a right sound port 134 embedded in the PCB 124. In an example, the directional microphone 104 and the oppositely phased directional microphone 106 have the same (or similar) configuration. For example, the directional microphone 104 and the oppositely phased directional microphone 106 are fabricated to be identical, which results in the directional microphone 104 and the oppositely phased directional microphone 106 having the same (or similar) configuration. In other examples, the directional microphone 104 and the oppositely phased directional microphone 106 may have configurations that are different from each other.

The directional microphone 104 is further supported by a substrate or PCB 136 and the oppositely phased directional microphone 106 is further supported by a substrate or PCB 138. The PCBs 136 and 138, respectively, are configured to transfer the signals of the microphones 104 and 106 to a computing device that may be external to the microphone module 100 or may be included as a part of the microphone module 100. The computing device may comprise a codec, digital signal processor, or microcontroller, for example. The computing device may be configured to perform processing and/or calculations (e.g., addition and/or subtraction) based on the signals of the microphones 104 and 106.

As a sound wave moves along direction 140, the sound wave first enters the sound port 120 of the directional microphone 104. As the sound wave enters the left sound port 120, the sound wave causes the cantilever 116 to bend upwards (e.g., away from the substrate 110), closer to (or towards) the fixed electrode 118. This decreases the gap between the cantilever 116 and fixed electrode 118 and increases the capacitance seen by the transducer 108. As a result, a positive signal is generated. As the sound wave continues to traverse along direction 140, the sound wave exits a top sound port 142 embedded in the lid 114 of the directional microphone 104. The sound wave then enters a top sound port 144 embedded in the lid 128 of the oppositely phased directional microphone 106. The cantilever 130 of microphone 106 bends downward (e.g., toward the substrate 124), away from fixed electrode 124. This increases the gap between cantilever 130 and fixed electrode 132 and decreases the capacitance seen by the transducer 122. As a result, a negative signal is generated. Finally the sound wave exits the sound port 134. When a sound wave traverses in the opposite direction of direction 140, the right oppositely phased directional microphone 106 outputs a positive signal and the directional microphone 104 outputs a negative signal. If the directional microphones 104 and 106 have the same design (or configuration), then the directional microphones 104 and 106 generate output signals that are equal (e.g., about equal) in amplitude and opposite in polarity. In other examples, the directional microphones 104 and 106 may have configurations different from each other but may still be configured such that the directional microphones 104 and 106 generate output signals that are equal (e.g., about equal) in amplitude and opposite in polarity.

The resting deflection of the MEMS transducers may vary in other cases. For example, in some examples, the moving cantilevers 116 and 130 may be initially deflected upwards. As another example, the moving cantilevers 116 and 130 may be initially deflected upwards and downwards (e.g., away from and toward the supporting substrate), respectively. The moving cantilevers 116 and 130 are accordingly deflected in the same direction or in different directions, in various examples. The moving cantilevers 116 and 130 may be deflected with about an equal amount of deflection.

Because the microphones 104 and 106 have outputs of equal amplitudes but opposite polarities, the subtraction of the two signals effectively doubles the amplitude of the resulting signal. Additionally, any signals of equal amplitude, phase, and polarity on both output signals are effectively canceled. This may help reduce unwanted noise that couples onto both the microphones 104 and 106 as well reduce distortion due to non-linearities during operation of the transducers. The signal outputs of microphone 104 and 106 may be subtracted to generate a differential output of the microphone module 100. In some examples, the signal outputs of microphone 104 and 106 may be subtracted in the computing device (e.g., the codec, digital signal processor, or microcontroller) that is external to the microphone module 100 or is included as a part of the microphone module 100.

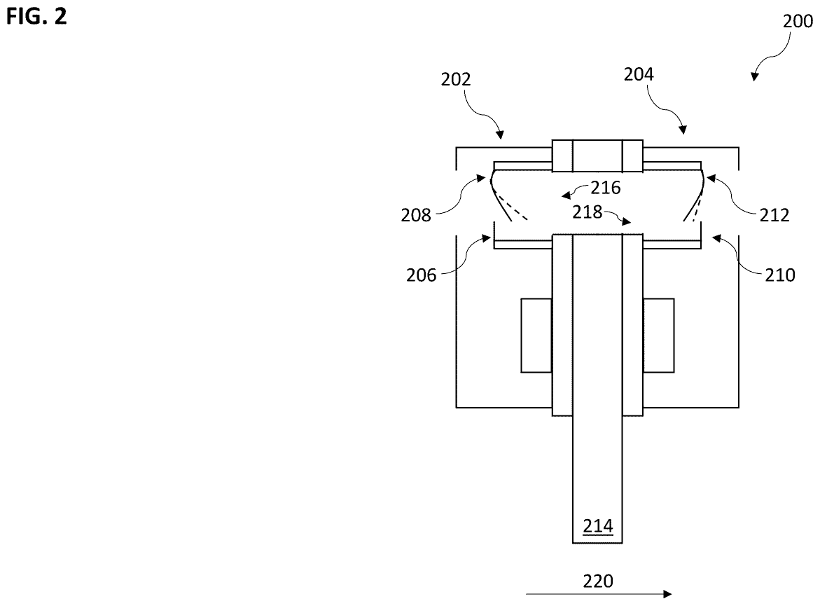

FIG. 2 depicts a system or device 200 in accordance with another example in which a differential signal is created using at least two directional microphones with a common substrate, such as a shared PCB. The system or device 200 is sometimes referred to herein as a “microphone module” 200. The microphone module 200 includes a directional microphone 202 and an oppositely phased directional microphone 204. The microphones 202, 204 may be similarly configured to the microphones 204, 206 described above with reference to FIG. 1. For instance, microphone 202 may be a directional microphone that includes a MEMS transducer 206 with a moving cantilever 208 with a downward-deflected rest position, and the microphone 204 may be an oppositely phased directional microphone that includes a MEMS transducer 210 with a moving cantilever 212 with a downward-deflected rest position.

The directional microphone 202 is supported by or mounted on a common substrate or PCB 214. The oppositely phased directional microphone 204 is mounted on the opposing side of PCB 214. In this example, the directional microphones 202 and 204 are mounted on the PCB 214 such that respective bottom sound ports 216 and 218 of the directional microphones 202, 204 are aligned with one another. The PCB 214 may be configured to transfer the signals of the microphones 202 and 204 to a computing device that may be external to the microphone module 200 or may be included as a part of the microphone module 200. The computing device may comprise a codec, digital signal processor, or microcontroller, for example. The computing device may be configured to perform processing and/or calculations (e.g., addition and/or subtraction) based on the signals of the microphones 202 and 204.

As a sound wave moves along direction 220, the sound wave first excites the MEMS transducer 206 of directional microphone 202. The sound wave causes the moving cantilever 208 to bend downwards (e.g., toward the supporting substrate) resulting in a negative signal as described in connection with FIG. 1. As the sound wave continues to traverse along direction 220, the sound wave then excites the MEMS transducer 210 of directional microphone 204. The sound wave causes the moving cantilever 212 to bend upwards (e.g., away from the supporting substrate) resulting in a positive signal as described in connection with FIG. 1. The signal outputs of microphone 202 and 204 may be subtracted to generate a differential output of the microphone module 100. If, for example, the directional microphones 202 and 204 have the same (or similar) design (configuration), then the microphones generate output signals that are equal (e.g., about equal) in amplitude and opposite in polarity and be subtracted appropriately as discussed in connection with the example of FIG. 1.

In some instances, if the two directional microphones are positioned such that respective sound ports thereof are aligned with one another, the total signal of the combined microphone output after subtracting the two signals may have reduced sensitivity. As a sound wave interacts with the first directional microphone transducer, the sound wave may lose some energy. That same sound wave with lower energy then proceeds to interact with the oppositely phased microphone. Because the oppositely phased microphone is excited by a sound wave with lower energy, the output of the oppositely phased microphone is not equal in amplitude as the first directional microphone, and the total output after subtracting the two signals is reduced.

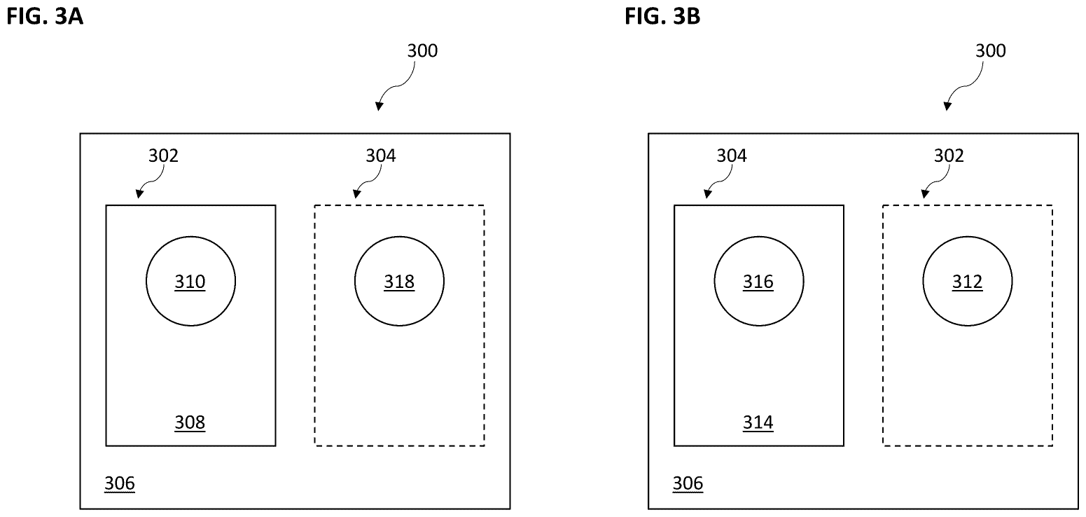

FIGS. 3A and 3B depict a system or device 300 in accordance with an example in which a differential signal is created using at least two directional microphones with misaligned sound ports. The system or device 300 is sometimes referred to herein as a “microphone module” 300. FIG. 3A depicts a front view of the device 300 and FIG. 3B depicts a back view of the microphone module 300. The microphone module 300 includes a directional microphone 302 and an oppositely phased directional microphone 304. The directional microphone 302 is mounted on a front side of a PCB 306, while the oppositely phased microphone 304 is mounted on a back side of the PCB 306. The directional microphone 302 has a lid 308 in which a top sound port 310 is embedded and a bottom sound port 312 embedded in the back side of PCB 306. The oppositely phased directional microphone 304 has a lid 314 in which a top sound port 316 is embedded and a bottom sound port 318 embedded in the front side of PCB 306. The PCB 306 may be configured to transfer the signals of the microphones 302 and 304 to a computing device that may be external to the microphone module 300 or may be included as a part of the microphone module 300. The computing device may comprise a codec, digital signal processor, or microcontroller, for example. The computing device may be configured to perform processing and/or calculations (e.g., addition and/or subtraction) based on the signals of the microphones 304 and 304. The signal outputs of microphone 302 and 304 may be subtracted to generate a differential output of the microphone module 300.

Sound ports 310 and 312 of directional microphone 302 are side-by-side with sound ports 316 and 318 of microphone 304, rather than aligned. The sound port 312 is thus offset from the sound port 310. Accordingly, unlike the examples of FIG. 1 and FIG. 2, where a sound wave passes through each directional microphone sequentially, a sound wave travelling in a direction perpendicular to the plane of PCB 306 passes through the directional microphones 302 and 304 in parallel. Thus, unlike the example of FIG. 2, where the sound wave may lose energy before arriving at the oppositely phased directional microphone, the sound wave arrives at the directional microphones 302 and 304 of module 300 with an equal amount of energy. Thus, the output of microphone 302 and 304 may be truly equal in amplitude, and provide maximum sensitivity when subtracting the two outputs.

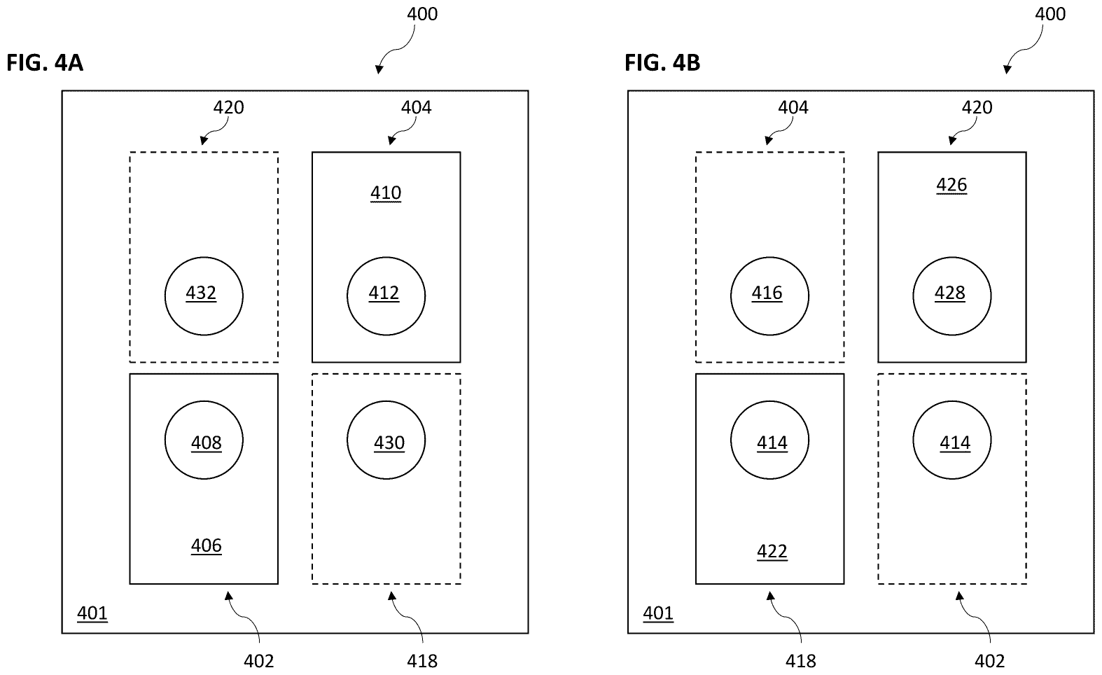

In some instances, it may be advantageous to create an assembly with greater than two directional microphones. FIGS. 4A and 4B depict a system or device 400 in accordance with an example in which more than two directional microphones are used to increase the signal-to-noise ratio (SNR) of the total system's output. The system or device 400 is sometimes referred to herein as a “microphone module” 400. FIG. 4A depicts a front view of the microphone module 400 and FIG. 4B depicts a back view of the microphone module 400. The microphone module 400 includes a first directional microphone 402 and a second directional microphone 404 mounted on the front side of a PCB 401. The directional microphone 402 and 404 are oriented such that they are relatively close in spacing. The directional microphone 402 has a lid 406 with embedded sound port 408 and directional microphone 404 has a lid 410 with embedded sound port 412 respectively. On the back side of the PCB 401, is an embedded sound port 414 that couples to microphone 402, and an embedded sound port 416 that couples to microphone 404.

The microphone module 400 also includes a third directional microphone 418 and a fourth directional microphone 420 mounted on the back side of a PCB 401. The directional microphone 418 and 420 are oriented such that they are relatively close in spacing. The directional microphone 418 has a lid 422 with embedded sound port 424 and directional microphone 420 has a lid 426 with embedded sound port 428 respectively. On the front side of the PCB 401, is an embedded sound port 430 that couples to microphone 418, and an embedded sound port 432 that couples to microphone 420. The PCB 401 may be configured to transfer the signals of the microphones 402, 404, 418, 420 to a computing device that may be external to the microphone module 400 or may be included as a part of the microphone module 400. The computing device may comprise a codec, digital signal processor, or microcontroller, for example. The computing device may be configured to perform processing and/or calculations (e.g., addition and/or subtraction) based on the signals of the microphones 402, 404, 418, 420.

In the microphone module 400, the directional microphones 402, 404, 418, 420 may have the same (or similar) design (configuration), so that the microphones generate output signals that are equal (e.g., about equal) in amplitude when subject to the same external stimulus (i.e., a sound wave). When adding the output signals of two similar microphones, the SNR of the resulting output typically increases by about 3 dB. Every doubling of microphones typically results in an SNR increase of about 3 dB. Thus, by using a total of four microphones in microphone module 400, a total of about 3 dB greater SNR can be achieved as compared to the two microphone system in microphone module 300.

Because microphones 402 and 404 sit on the same front plane of the PCB 401, their outputs are in phase with on another when exposed to external sound. Similarly, the outputs of microphones 418 and 420 are in phase with one another. Thus, when combining the signals in microphone module 400, a first sum signal may be obtained by adding the output of microphone 402 to the output of microphone 418. A second sum signal may be obtained by adding the output of microphone 418 to the output of microphone 420. In this case, the first and second sum signals have an SNR that is about 3 dB higher than the SNR of a single directional microphone 402. However, the first and second sum signals are out of phase from one another, since they represent microphones on the front and back side of PCB 401 respectively. Thus, the first sum signal and second sum signal may be subtracted to create a differential output signal for microphone module 400. This differential output signal has about a 6 dB increase in SNR relative to a single directional microphone 402 and additionally has all the benefits from combining differential signals as described in FIG. 2 and FIG. 3.

In some examples, more than four directional microphones may be used to further increase the SNR of the device. For example, by using a total of eight directional microphones (four on each side of the PCB), an output signal with about 9 dB higher SNR than a single directional microphone may be created. Generally, the microphone module 400 may include one or more first microphones (e.g., one or more microphones 408) and one or more second microphones (e.g., one or more microphones 412) that are arranged in the microphone module 400 (e.g., on a first side of the PCB 401) to generate respective first signals that are in phase with each other when a sound wave traverses the microphone module 400. The microphone module 400 may also include one or more third microphones (e.g., one or more microphones 430) and one or more fourth microphones (e.g., one or more microphones 432) that are arranged (e.g., on a second, opposing, side of the PCB 401) to generate respective second signals that are in phase with each other when a sound wave traverses the microphone module 400, but have opposite phases from the phases of the first signals. The first signals may be added together to generate a first sum signal, and the second signals may be added together to generate a second sum signal. The first and the second sum signals may then be subtracted to generate a differential output of the microphone module 400.

It should further be noted that the sound ports of the four directional microphones in microphone module 400 are oriented to be centered in the PCB 401, and as close to one another as possible. The sound ports are relatively equidistant from the edges of the PCB 401. This helps maintain symmetry and makes for more similar output signals of the individual microphones, as opposed to if one of the microphone sound ports were placed alongside the edge of the microphone PCB 401 while the remaining microphones were centered. Additionally, as the microphones are exposed to ambient sound waves travelling perpendicular to the PCB 401, the sound wave must hit the first sound port in the microphone, and wrap around the PCB 401 before reaching the second sound port of the PCB. The longer the length that the sound wave has to travel, the larger the pressure difference seen by the microphone across its two sound ports. This leads to an increase in sensitivity, and thus SNR, of an individual microphone. By placing the microphone sound ports in the center of the PCB 401, the length that the sound wave has to travel between both sound ports of a respective microphones increases compared to if the sound ports were oriented closer to the edge of the PCB 401.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A microphone module, comprising:
a first microelectromechanical system (MEMS) transducer comprising a first cantilever and a first fixed electrode; and
a second MEMS transducer comprising a second cantilever and a second fixed electrode,
wherein the first MEMS transducer and the second MEMS transducer are arranged in the microphone module such that when a sound wave traverses the microphone module the sound wave causes the first MEMS transducer and the second MEMS transducer to move in different directions with respect to each other.

2. The microphone module of claim 1, wherein the first MEMS transducer and the second MEMS transducer are arranged in the microphone module such that when a sound wave traverses the microphone module the sound wave causes the first MEMS transducer and the second MEMS transducer to move in different directions that are opposite of each other.

3. The microphone module of claim 1, further comprising a first sound port and a second sound port, wherein the first MEMS transducer is positioned in the microphone module over the first sound port and the second MEMS transducer is positioned in the microphone module over the second sound port.

4. The microphone module of claim 3, wherein the first sound port is offset from the second sound port.

5. The microphone module of claim 3, wherein the first sound port and the second sound port are aligned with each other.

6. The microphone module of claim 1, wherein the first MEMS transducer and the second MEMS transducer are fabricated to be identical to each other.

7. The microphone module of claim 1, wherein the first MEMS transducer and the second MEMS transducer are arranged such that, as the sound wave traverses the microphone module, the sound wave makes the first cantilever move towards the first fixed electrode as the second cantilever is moving away from the second fixed electrode.

8. The microphone module of claim 1, wherein:
the first cantilever has an equilibrium position such that the first cantilever is deflected in a first direction relative to the first fixed electrode; and
the second cantilever has an equilibrium position such that the second cantilever is deflected in the first direction relative to the second fixed electrode.

9. The microphone module of claim 1, wherein:
the first cantilever has an equilibrium position such that the first cantilever is deflected downwards relative to the first fixed electrode; and
the second cantilever has an equilibrium position such that the second cantilever is deflected downwards relative to the second fixed electrode.

10. The microphone module of claim 1, further comprising a first substrate that supports the first MEMS transducer and a second substrate that supports the second MEMS transducer.

11. The microphone module of claim 10, further comprising a common substrate, wherein the first substrate that supports the first MEMS transducer and the second substrate that supports the second MEMS transducer are mounted on opposing sides of the common substrate.

12. The microphone module of claim 11, wherein the common substrate comprises a printed circuit board (PCB).

13. The microphone module of claim 10, further comprising:
a first lid positioned over the first substrate and enclosing the first MEMS transducer; and
a second lid positioned over the second substrate and enclosing the second MEMS transducer.

14. The microphone module of claim 1, wherein
the first MEMS transducer is configured to generate a first output signal when the sound wave traverses the microphone module,
the second MEMS transducer is configured to generate a second output signal when the sound wave traverses the microphone module, wherein the second output signal is opposite in phase relative to the first output signal.

15. The microphone module of claim 14, wherein the first output signal and the second output signal are subtracted to generate a differential output of the microphone module.

16. The microphone module of claim 1, further comprising:
one or more third MEMS transducers, each of the one or more third MEMS transducers comprising a third cantilever and a third fixed electrode; and
one or more fourth MEMS transducers, each of the one or more fourth MEMS transducers comprising a fourth cantilever and a fourth fixed electrode,
wherein the one or more third MEMS transducers and the one or more fourth MEMS transducers are arranged in the microphone module such that as the sound wave traverses the microphone module the sound wave causes the one or more third MEMS transducer and the one or more fourth MEMS transducer to move in different directions with respect to each other.

17. The microphone module of claim 16, wherein:
the first MEMS transducer and the one or more third MEMS transducers are arranged such that, as the sound wave traverses the microphone module, the sound wave causes the first MEMS transducer and the one or more third MEMS transducers to move in a same direction with respect to each other; and
the second MEMS transducer and the one or more fourth MEMS transducers are arranged such that, as the sound wave traverses the microphone module, the sound wave causes the second MEMS transducer and the one or more fourth MEMS transducers to move in a same direction with respect to each other.

18. The microphone module of claim 17, wherein:
a first output signal generated by the first MEMS transducer and one or more third output signals generated by respective ones of the ones of more third MEMS transducers are summed to generate a first sum output signal;
a second output signal generated by the second MEMS transducer and one or more fourth output signals generated by respective ones of the one or more fourth MEMS transducers are summed to generate a second sum output signal; and
the first sum output signal and the second sum output signal are subtracted to generate a differential output of the microphone module.

19. A microphone module, comprising:
a first microelectromechanical system (MEMS) transducer comprising a first cantilever and a first fixed electrode; and
a second MEMS transducer comprising a second cantilever and a second fixed electrode,
wherein the first MEMS transducer and the second MEMS transducer are arranged in the microphone module such that, when a sound wave traverses the microphone module, the sound wave causes the first MEMS transducer and the second MEMS transducer to generate respective output signals that are opposite in phase with respect to each other.

20. A microphone module, comprising:
a first microelectromechanical system (MEMS) transducer comprising a first cantilever and a first fixed electrode;
a second MEMS transducer comprising a second cantilever and a second fixed electrode; and
a common substrate that supports the first MEMS transducer and the second MEMS transducer,
wherein the first MEMS transducer and the second MEMS transducer are positioned on opposing sides of the common substrate such that, when a sound wave traverses the microphone module, the sound wave causes the first MEMS transducer and the second MEMS transducer to generate respective output signals that are opposite in phase with respect to each other.
